(19) United States
(12) Patent Application Publication
(10) Pub. No.: US 2011/0203655 A1
(43) Pub. Date: Aug. 25, 2011

(54) PHOTOVOLTAIC DEVICE PROTECTION LAYER

(75) Inventors: Markus E. Beck, Scotts Valley, CA (US); Raffi Garabedian, Los Altos, CA (US)

(73) Assignee: First Solar, Inc., Perrysburg, OH (US)

(21) Appl. No.: 13/025,439

(22) Filed: Feb. 11, 2011

Related U.S. Application Data
(60) Provisional application No. 61/306,831, filed on Feb. 22, 2010.

(51) Int. Cl. H01L 31/0203; H01L 31/18

(52) U.S. Cl. 136/256; 438/64; 257/E31.117

(57) ABSTRACT

A photovoltaic structure can include a protective cap, which can include sodium.

### CLAIM OF PRIORITY

This application claims priority to U.S. Provisional Patent Application No. 61/306,831, filed on Feb. 22, 2010, which is incorporated by reference in its entirety.

### TECHNICAL FIELD This invention relates to a protective cap layer for a photovoltaic device.

### BACKGROUND

Copper indium gallium selenide (CIGS) based photovoltaic devices can be made from high temperature vacuum processes. Using glass as a substrate can be beneficial as the glass plate provides mechanical support as well as a smooth surface for high quality film growth. However, a heat treating process to strengthen the glass substrate after CIGS deposition can give rise to some other problems, such like CIGS degradation, equipment and process cost increase. Furthermore, exposure of CIGS to ambient results in CIGS surface oxidation, in turn diminishing device performance.

### DESCRIPTION OF DRAWINGS

FIG. 1 is a schematic showing the thermal evaporation deposition process of the CIGS layer.

FIG. 2 is a schematic of a CIGS photovoltaic device.

FIG. 3 is a schematic of a film stack including a protective cap layer adjacent to the semiconductor absorber layer.

### DETAILED DESCRIPTION

Photovoltaic devices can include multiple layers formed on a substrate (or superstrate). Copper indium gallium selenide (CIGS) based photovoltaic devices can be made from high temperature vacuum processes, such as co-evaporation, reaction of stacked elemental layers, or selenization of metal precursors. For example, a photovoltaic device can include a transparent conductive oxide (TCO) layer, a buffer layer, a semiconductor layer, and a conductive layer formed adjacent to a substrate. The semiconductor layer can include a semiconductor window layer and a semiconductor absorber layer, which can absorb photons. The semiconductor absorber layer can include CIGS. Each layer in a photovoltaic device can be created (e.g., formed or deposited) by any suitable process and can cover all or a portion of the device and/or all or a portion of the layer or substrate underlying the layer. For example, a “layer” can mean any amount of any material that contacts all or a portion of a surface.

Copper indium (di) selenide (CIS) and their alloys with gallium (CIGS) have the requisite optoelectronic properties (high optical absorption coefficient, favorable bandgaps, suitable resistivity etc.) for photovoltaic (PV) applications. Moreover, polycrystalline CIS and CIGS solar cells can outperform their monocrystalline counterparts. A variety of techniques were used in the preparation of these materials. The best cell efficiencies can be obtained on materials prepared with the co-evaporation of elements technique. Co-evaporation of CIGS thin film via two-stage and three-stage processes has been widely used.

From a product perspective, using glass as a substrate in a CIGS photovoltaic device can be beneficial as the glass plate provides mechanical support as well as a smooth surface for high quality film growth. In addition, if a sodium-containing glass is used, it can serve as the source of sodium during film growth. However, glass can fracture when its surfaces or edges are placed into tension. Under these conditions, inherent surface or edge fissures may propagate into visible cracks. The basic principle employed in a heat treating process is to create an initial condition of surface and edge compression. This condition is achieved by first heating the glass, then cooling the surfaces rapidly. This leaves the center glass thickness relatively hot compared to the surfaces. As the center thickness then cools, it forces the surfaces and edges into compression. In some embodiment, glass can only withstand certain mechanical loads and the heat as well as cool-down rates need to be considered as well. The mechanical strength of a glass plate is a strong function of the thermal history of that plate. Glass is typically produced in an annealed condition (with minimal internal stress). Annealed glass tends to be fragile since mechanical strain causes micro-cracks present on the glass surface (called Grifith cracks) to propagate. Grifith crack defects cause the working tensile strength of soda-lime glass plate to typically be around 2000 psi, which is lower than the theoretical strength of bulk glass.

In order to overcome this fragility problem, glass plate is often quench strengthened by heating to a temperature sufficient to soften the glass (e.g., to 650° C., known as softening point), and then cooling rapidly (e.g., to 450° C., known as annealing point). The rapid cooling process can cause the exterior of the glass to harden while the core is still viscous and can relax to accommodate the thermal contraction of the hardened surface. Subsequent hardening of the core (center) of the glass below the annealing temperature causes it to solidify and then shrink, which puts the surfaces of the glass in compression. The resulting built-in compressive surface stress can allow the glass plate to withstand greater bending stresses before the tensile strength limit is reached. This strengthening process can be called “tempering.” The rapid cooling from the softening point to the annealing point can be accomplished in practice by directing high pressure jets of cooling gas onto the glass surface from both sides. In some cases liquid cooling is even used in order to maximize the “temper,” or surface compressive stress. In order to achieve rapid cooling heat transport via conduction is necessary. The latter could be achieved via a purge with helium or nitrogen gas at high flow rates.

Quench strengthening of the glass substrate can cause Se to desorb from the deposited CIGS film surface during the gas-flow cooling process, leaving behind Se vacancies in the lattice. The latter can reduce the voltage and efficiency of the resulting device. Thus, cool down is typically in a slight Se overpressure atmosphere down to 300° C., at which point the desorption loss of Se out of the CIGS surface becomes negligible. This is due to the fact that the partial pressure of Se above the CIGS becomes very small. Due to the heat capacity of the glass long vacuum cool down times are required making in-line CIGS coaters very long, or cool down sequences batch ovens very time consuming. This in turn increases production cost.

Air exposure of the CIGS absorber layer results in oxidation of the surface. Some of the resulting oxides can be removed in a subsequent process step, possibly in combination with the deposition of a buffer layer.

Another aspect of CIGS device processing is related to the fact that the band gap of the chalcopyrite semiconductor can be modified via interchanging elements. The most common two approaches are exchanging a portion of In with Ga or some of the Se with S. In conversion of metal or stacked elemental layers for CIGS formation it is difficult to accomplish the optimal surface band gap gradient via Ga and a combination of Ga and S grading is used. In a multi-stage co-evaporation process band gap grading via Ga alone is possible.

As discussed above, if a Na-containing glass is used as the substrate the Na in the glass can serve as the source of Na during film growth. The addition of Na during CIGS formation has been found to be critical for high-efficient devices. More recently it has been shown that a Na treatment step post CIGS growth can also improve the quality of the CIGS absorber and subsequent PV device.

To address the above aspects, a fast quench and oxidation protective cap layer on the CIGS absorber layer can be used. The concept is based on the use of a compatible material, e.g. Na₂Se, deposited onto the CIGS absorber layer prior to quench. When a thin, ideally pinhole free, layer of cap layer is deposited, it can prevent subsequent Se loss from the electrically active junction area of the device during quench cool down by providing a Se-rich passivation layer. Use of a Na-containing compound can also serve as a post CIGS source for Na. Furthermore, this cap layer can allow for more rapid quench conditions and protect the CIGS surface from damage and oxidation. Less cool down times required in making in-line CIGS coaters can result in production cost reduction.

In one aspect, a method of manufacturing a structure includes forming a conductive layer adjacent to a substrate, forming a semiconductor absorber layer adjacent to the conductive layer, wherein the semiconductor absorber layer includes copper indium gallium selenide, and forming a protective cap layer adjacent to the absorber layer. The method can include removing the protective cap layer, forming a semiconductor buffer layer adjacent to the semiconductor absorber layer, and forming a transparent conductive oxide layer adjacent to the buffer layer. The method can include heating the substrate to soften the glass substrate after forming the protective cap and cooling the substrate to solidify and strengthen the glass substrate.

Cooling the substrate can include directing a fluid stream of coolant toward a surface of the glass substrate. The fluid stream can include helium. The fluid stream can include nitrogen. The fluid stream can include selenium. The fluid stream can include a gas. The fluid stream can include a liquid. Heating the substrate can include heating the substrate to a softening point temperature. Softening point temperature can be in the range of 500 degree C. to 800 degree C. Cooling the substrate stack can include cooling the substrate to an annealing point temperature. The annealing point temperature can be less than 500 degree C.

Forming the semiconductor absorber layer can include co-evaporating of a plurality of elements. Forming the semiconductor absorber layer can include forming and reacting a plurality of stacked elemental layers. Forming the semiconductor absorber layer can include forming and selenizing a metal precursor layer. Forming the semiconductor absorber layer can include modifying the photovoltaic device band gap by interchanging a plurality of elements. Forming the semiconductor absorber layer can include modifying the photovoltaic device band gap by exchanging a portion of indium with a portion of gallium. Forming the semiconductor absorber layer can include modifying the photovoltaic device band gap by exchanging a portion of selenium with a portion of sulfur.

The protective cap layer can include sodium. The protective cap layer can include a selenide. The protective cap layer can include sodium selenide. The protective cap layer can include a sulfide. The protective cap layer can have a thickness less than 1000 angstrom. The protective cap layer can have a thickness in the range of 200 angstrom to 600 angstrom. The protective cap layer can include a water soluble material. The method can include removing all or a portion of the protective cap layer after the step of cooling the substrate. The step of removing a portion of the protective cap layer can include contacting an aqueous medium to the protective cap layer.

In one aspect, a photovoltaic structure can include a substrate, a conductive layer adjacent to the substrate, a semiconductor absorber layer adjacent to the conductive layer, and a protective cap layer adjacent to the absorber layer. The absorber layer can include copper indium gallium selenide. The photovoltaic device can include a protective cap layer adjacent to the absorber layer.

The protective cap layer can include sodium. The protective cap layer can include a selenide. The protective cap layer can include sodium selenide. The protective cap layer can include a sulfide. The protective cap layer can have a thickness less than 1000 angstrom. The protective cap layer can have a thickness in the range of 200 angstrom to 600 angstrom. The protective cap layer can include a water soluble material. The structure can include a semiconductor buffer layer adjacent to the semiconductor absorber layer. The absorber layer can include copper indium gallium selenide. The structure can include a transparent conductive oxide layer adjacent to the buffer layer.

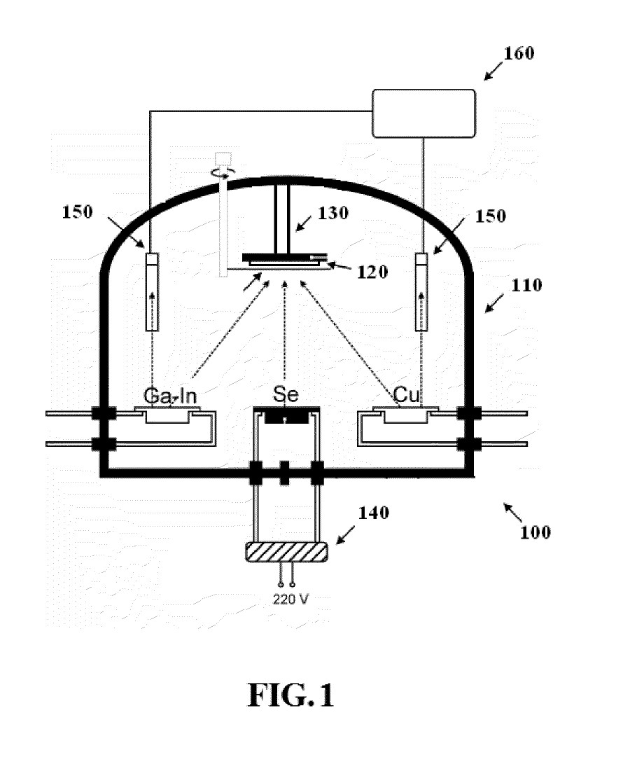

Referring to FIG. 1, CIGS film thermal evaporation system 100 can include chamber 110. Chamber 110 can be connected to a vacuum system which allows working at pressures of about 10⁻⁵ to about 10⁻⁷, (for example about 10⁻⁶) Torr. System 100 can include three boats (used to evaporate Se, In+Ga and Cu, respectively) and thickness monitor 160 with quartz crystal sensor 150, which can be used for measuring the flux rate of the evaporated elements. System 100 can include programmable power source and related controller 140. Substrate 120 can be mounted on mounting fixture 130 or positioned in any other suitable manner. Substrate 120 can be a glass substrate. System 100 can optionally include any suitable substrate heating module. Mounting fixture 130 can be rotary and can hold substrate 120 facing down. In some embodiments, an evaporation process can be multi-stage and involve multi-species. An evaporation process can include co-evaporation. In some embodiments, the CIGS deposition system can be an in-line, multi-stage (e.g., three-stage) deposition system capable of continuous processing of moving substrates. Several evaporation sources can be used in an in-line configuration in the system.

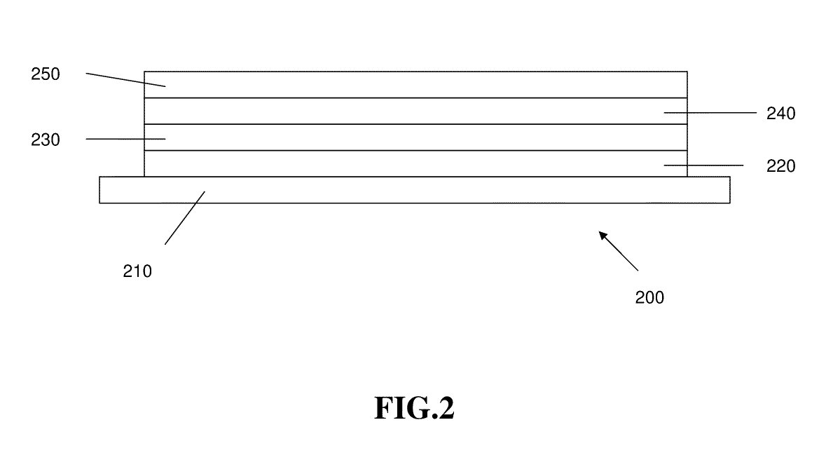

Referring to FIG. 2, photovoltaic device 200 can include substrate 210, conductive layer 220, semiconductor absorber layer 230, semiconductor buffer layer 240 and transparent conductive oxide layer 250. Substrate 210 can include glass or any other suitable material. Substrate 210 can include soda-lime glass. Conductive layer 220 can include any suitable material. For example, conductive layer 220 can include any suitable metal. Semiconductor buffer layer 240 can include cadmium sulfide or any other suitable material. Optionally, photovoltaic device 200 can include a barrier layer formed between substrate 210 and conductive layer 220. Photovoltaic device 200 can also include an optional window layer formed between transparent conductive oxide layer 250 and semiconductor buffer layer 240. Semiconductor absorber layer 230 can include any suitable material. Semiconductor absorber layer 230 can include one or more of copper, indium, gallium, sulfur, and/or selenium. Semiconductor absorber layer 230 can include copper indium (di) selenide (CIS) and their alloys with gallium (CIGS) and/or sulfur (CIGSSe).

The layers included in FIG. 2 can be created by any suitable method. For example, one or more of the layers can be formed or deposited on the underlying layer or substrate. The layers can be deposited by any suitable method of sputtering, CVD, PVD, or any other suitable technology. For example, semiconductor absorber layer 230 can be formed by co-evaporating a plurality of elements. Semiconductor absorber layer 230 can be formed by creating and reacting a plurality of stacked elemental layers, for example, layers of one or more than one of copper, indium, gallium, and selenium. Forming semiconductor absorber layer 230 can include modifying the band gap of photovoltaic device 200 by interchanging a plurality of elements included in semiconductor absorber layer 230, for example, by exchanging a portion of indium with a portion of gallium, or exchanging a portion of selenium with a portion of sulfur.

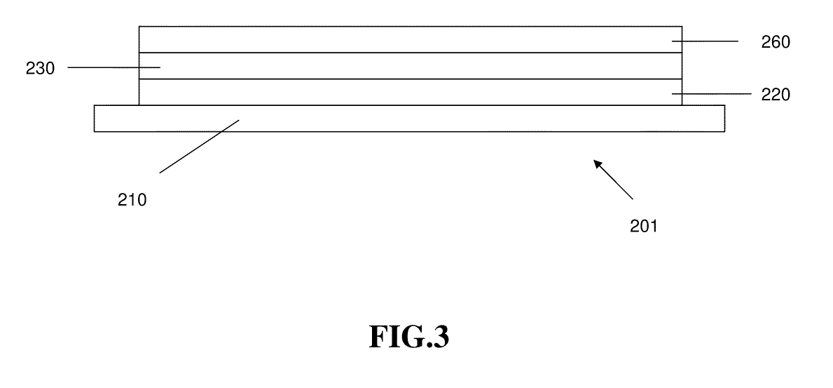

Referring to FIG. 3, structure 201 can include a film stack, which can include a plurality of adjacent film layers formed on substrate 210. Structure 201 can include protective cap layer 260. Protective cap layer 260 can include any suitable material. For example, protective cap layer 260 can include sodium. Protective cap layer 260 can include selenium. Protective cap layer 260 can include sodium selenide (Na₂Se). Protective cap layer can include sulfur. Protective cap layer 260 can have any suitable mean equivalent thickness. For example, protective cap layer 260 can have a mean equivalent thickness of less than 1000 angstroms. Protective cap layer 260 can have a mean equivalent thickness of between 200 and 600 angstroms. Protective cap layer 260 can have a thickness of 500 angstroms. Protective cap layer 260 can include a water soluble material.

Protective cap layer 260 can be formed by any suitable method. For example, protective cap layer 260 can be created by any suitable deposition means. After protective cap layer 260 is formed adjacent to semiconductor absorber layer 230, structure 201 can be heated to soften substrate 210 and subsequently cooled (e.g., in a quench process) to solidify and/or strengthen substrate 210, for example in cases where substrate 210 includes glass. Heating structure 201 can include heating substrate 210 to a softening point temperature of substrate 210. The softening point temperature can be any suitable temperature to soften the substrate. For example, the softening point temperature can be in the range of 500 degrees C. to 800 degrees C.

Structure 201 and/or substrate 210 can be subsequently cooled by any suitable method. For example, substrate 210 can be cooled by directing a fluid stream of coolant toward a surface of the substrate. The fluid stream can include a gas and/or a liquid. The fluid stream can include any suitable material. For example, the fluid stream can include helium, nitrogen, or selenium. Substrate 210 can be cooled to a temperature at or below its annealing point. The annealing point can be, for example, 500 degrees C.

In some embodiments, use of a sodium-containing protective cap layer 260 deposited at high temperatures could provide sodium-dosing in case of sodium-free substrates as an alternative of pre-CIGS growth deposition of a sodium-containing precursor onto the back contact coated substrate. Sodium sulfide is also readily soluble in water. Moreover, using sodium sulfide can allow for optimized surface band gap grading with or without the combination of gallium.

Referring to FIG. 3, in some embodiments, protective cap layer 260 can be removed in such a manner not to damage the CIGS surface. Protective cap layer 260 can include some water soluble material so that its removal can be done as part of a following aqueous buffer deposition step. The aqueous buffer deposition step can also remove excess sodium that diffuses from the glass during CIGS growth (the sodium is oxidized, and sodium oxide is water soluble).

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A method of manufacturing a structure comprising the steps of:
forming a conductive layer adjacent to a substrate;
forming a semiconductor absorber layer adjacent to the conductive layer, wherein the semiconductor absorber layer comprises copper indium gallium selenide; and
forming a protective cap layer adjacent to the absorber layer.

2. The method of claim 1, further comprising:
removing the protective cap layer;
forming a semiconductor buffer layer adjacent to the semiconductor absorber layer; and
forming a transparent conductive oxide layer adjacent to the buffer layer.

3. The method of claim 1, further comprising:
heating the substrate to soften the glass substrate after forming the protective cap; and
cooling the substrate to solidify and strengthen the glass substrate.

4. The method of claim 3, wherein cooling the substrate comprises directing a fluid stream of coolant toward a surface of the glass substrate.

5. The method of claim 3, wherein the fluid stream comprises one or more of helium, nitrogen, selenium, a gas, or a liquid.

6. The method of claim 2, wherein heating the substrate comprises heating the substrate to a softening point temperature.

7. The method of claim 6, wherein the softening point temperature is in the range of 500 degree C. to 800 degree C.

8. The method of claim 2, wherein cooling the substrate stack comprises cooling the substrate to an annealing point temperature.

9. The method of claim 8, wherein the annealing point temperature is less than 500 degree C.

10. The method of claim 1, wherein forming the semiconductor absorber layer comprises co-evaporating of a plurality of elements.

11. The method of claim 1, wherein forming the semiconductor absorber layer comprises forming and reacting a plurality of stacked elemental layers.

12. The method of claim 1, wherein forming the semiconductor absorber layer comprises forming and selenizing a metal precursor layer.

13. The method of claim 1, wherein forming the semiconductor absorber layer comprises modifying the photovoltaic device band gap by interchanging a plurality of elements.

14. The method of claim 1, wherein forming the semiconductor absorber layer comprises modifying the photovoltaic device band gap by exchanging a portion of indium with a portion of gallium.

15. The method of claim 1, wherein forming the semiconductor absorber layer comprises modifying the photovoltaic device band gap by exchanging a portion of selenium with a portion of sulfur.

16. The method of claim 1, wherein the protective cap layer comprises one or more of sodium, selenide, sodium selenide, or sulfide.

17. The method of claim 1, wherein the protective cap layer has a thickness less than 1000 angstrom.

18. The method of claim 1, wherein the protective cap layer comprises a water soluble material.

19. The method of claim 2, wherein removing the protective cap layer comprises removing all or a portion of the protective cap layer after the step of cooling the substrate.

20. The method of claim 19, wherein the step of removing all or a portion of the protective cap layer comprises contacting an aqueous medium to the protective cap layer.

21. A structure comprising:
a substrate;
a conductive layer adjacent to the substrate;
a semiconductor absorber layer adjacent to the conductive layer; and
a protective cap layer adjacent to the absorber layer.

22. The structure of claim 21, wherein the protective cap layer comprises one or more of sodium, selenide, sodium selenide, or sulfide.

23. The structure of claim 21, wherein the protective cap layer has a thickness less than 1000 angstrom.

24. The structure of claim 21, wherein the protective cap layer comprises a water soluble material.

25. The structure of claim 21, further comprising a semiconductor buffer layer
adjacent to the semiconductor absorber layer, wherein the absorber layer comprises copper indium gallium selenide; and
a transparent conductive oxide layer adjacent to the buffer layer.
